(19) United States
(12) Patent Application Publication
(10) Pub. No.: US 2026/0107371 A1
(43) Pub. Date: Apr. 16, 2026

(54) PRINTED CIRCUIT BOARD ASSEMBLY INCLUDING INTERPOSER CIRCUIT

(71) Applicant: Samsung Electronics Co., Ltd., Suwon-si (KR)

(72) Inventors: Jongyeon KIM, Suwon-si (KR); Eunsoo PARK, Suwon-si (KR); Kyungsoo JANG, Suwon-si (KR); Junsoo LEE, Suwon-si (KR); Yongwoon KIM, Suwon-si (KR)

(21) Appl. No.: 19/388,013

(22) Filed: Nov. 13, 2025

Related U.S. Application Data
(63) Continuation of application No. PCT/KR2025/015179, filed on Sep. 26, 2025.

(30) Foreign Application Priority Data
Oct. 14, 2024 (KR) 10-2024-0139739
Nov. 8, 2024 (KR) 10-2024-0158041

(51) Int. Cl. H05K 1/02; H05K 1/14

(52) U.S. Cl. CPC H05K 1/0201; H05K 1/0215; H05K 1/144; H05K 2201/064; H05K 2201/10378

(57) ABSTRACT

A printed circuit board assembly is provided. The printed circuit board assembly includes a first printed circuit board, a second printed circuit board, a first interposer circuit at least partially surrounding a first space between the first printed circuit board and the second printed circuit board, and a thermally conductive material arranged within the first space, wherein the first interposer circuit has a first ventilation path, wherein the first ventilation path connects a first end formed at an outer side, facing the outside, of the first portion of the first interposer circuit and a second end formed at an inner side, facing the first space, of the first portion, and wherein the length of the first ventilation path is greater than the width of a part of the first interposer circuit in which the first ventilation path is formed.

### CROSS-REFERENCE TO RELATED APPLICATION(S)

This application is a continuation application, claiming priority under 35 U.S. C. § 365(c), of an International application No. PCT/KR2025/015179, filed on Sep. 26, 2025, which is based on and claims the benefit of a Korean patent application number 10-2024-0139739, filed on Oct. 14, 2024, in the Korean Intellectual Property Office, and of a Korean patent application number 10-2024-0158041, filed on Nov. 8, 2024, in the Korean Intellectual Property Office, the disclosure of each of which is incorporated by reference herein in its entirety.

### TECHNICAL FIELD

The disclosure relates to a printed circuit board assembly including an interposer circuit.

### BACKGROUND ART

With the development of technologies, the number of electronic components provided inside electronic devices is increasing, and the electronic devices are becoming smaller and slimmer. Accordingly, technologies of arranging a plurality of electronic components inside the electronic device are becoming important, and technologies of stacking a plurality of circuit boards including the plurality of electronic components by using an interposer are being developed.

The above information is presented as background information only to assist with an understanding of the disclosure. No determination has been made, and no assertion is made, as to whether any of the above might be applicable as prior art with regard to the disclosure.

### DISCLOSURE

Aspects of the disclosure are to address at least the above-mentioned problems and/or disadvantages and to provide at least the advantages described below. Accordingly, an aspect of the disclosure is to provide a printed circuit board assembly including an interposer circuit.

Additional aspects will be set forth in part in the description which follows and, in part, will be apparent from the description, or may be learned by practice of the presented embodiments.

### TECHNICAL SOLUTION

In accordance with an aspect of the disclosure, a printed circuit board assembly is provided. The printed circuit board assembly includes a first printed circuit board, a second printed circuit board, a first interposer circuit at least partially surrounding a first space between the first printed circuit board and the second printed circuit board, and a thermally conductive material arranged within the first space, wherein the first interposer circuit has a first ventilation path through which air moves from the first space to the outside of the printed circuit board assembly when the thermally conductive material is injected into the first space through a first hole formed in the first printed circuit board, wherein the first ventilation path connects a first end formed at an outer side, facing the outside of the printed circuit board assembly, of a first portion of the first interposer circuit, to a second end formed at an inner side, facing the first space, of the first portion of the first interposer circuit, and wherein the length of the first ventilation path is greater than the width of a part of the first interposer circuit in which the first ventilation path is formed.

In accordance with another aspect of the disclosure, a printed circuit board assembly is provided. The printed circuit board assembly includes a first printed circuit board including a first opening, a second printed circuit board, an interposer circuit arranged to at least partially surround a space between the first printed circuit board and the second printed circuit board, and a thermally conductive material injected into the space, wherein the interposer circuit includes a recess formed at an inner side of a first portion of the interposer circuit in a direction of facing the outside of the printed circuit board assembly, wherein the first opening of the first printed circuit board is formed in a position corresponding to the recess of the interposer circuit, and wherein a ventilation path through which air moves from the space to the outside of the printed circuit board assembly is formed by the recess and the first opening.

Other aspects, advantages, and salient features of the disclosure will become apparent to those skilled in the art from the following detailed description, which, taken in conjunction with the annexed drawings, discloses various embodiments of the disclosure.

### DESCRIPTION OF DRAWINGS

The above and other aspects, features, and advantages of certain embodiments of the disclosure will be more apparent from the following description taken in conjunction with the accompanying drawings, in which:

FIG. 1 is an exploded perspective view of an electronic device according to an embodiment of the disclosure;

FIG. 2 is an exploded perspective view of a printed circuit board assembly according to an embodiment of the disclosure;

FIG. 3 is a perspective view of a printed circuit board assembly according to an embodiment of the disclosure;

FIG. 4 is a cross-sectional view of a section taken along line A-A′ of FIG. 3 according to an embodiment of the disclosure;

FIG. 5 is a diagram illustrating the positions of a first end and a second end of a first ventilation path according to an embodiment of the disclosure;

FIG. 6 is a diagram illustrating the shape of a first ventilation path according to an embodiment of the disclosure;

FIG. 7 is a diagram illustrating an example of a first kit formed by coupling a first interposer circuit to a first bridge portion according to an embodiment of the disclosure;

FIG. 8 is a diagram illustrating an example of a first interposer circuit in which a first bridge portion is cut off according to an embodiment of the disclosure;

FIG. 9 is a diagram illustrating an example in which a first interposer circuit is coupled to a second printed circuit board coupled to a second bridge portion according to an embodiment of the disclosure;

FIG. 10 is a diagram illustrating an example in which a second bridge portion is cut off in a state in which the first interposer circuit is coupled to the second printed circuit board of FIG. 9 according to an embodiment of the disclosure;

FIG. 11 is a diagram illustrating an example of a plurality of conductors formed in a first interposer circuit according to an embodiment of the disclosure;

FIG. 12 is a diagram illustrating an example of a grounding pad composed of a plurality of conductors according to an embodiment of the disclosure;

FIG. 13 is a cross-sectional view of a section taken along line B-B′ of FIG. 12 according to an embodiment of the disclosure;

FIG. 14 is a diagram illustrating an example of a pipe connected to a first ventilation path according to an embodiment of the disclosure;

FIG. 15 is a diagram illustrating an example of a second ventilation path formed in a third portion of a first interposer circuit according to an embodiment of the disclosure;

FIG. 16 is a diagram illustrating an example of a first ventilation path formed by a first groove and a second groove according to an embodiment of the disclosure;

FIG. 17 is a diagram illustrating an example of a third ventilation path formed in a second interposer circuit according to an embodiment of the disclosure;

FIG. 18 is a diagram illustrating an example of a first ventilation path according to an embodiment of the disclosure;

FIG. 19 is a diagram illustrating an example of a first interposer circuit including a recess according to an embodiment of the disclosure; and

FIG. 20 is a block diagram of an electronic device in a network environment according to an embodiment of the disclosure.

Throughout the drawings, it should be noted that like reference numbers are used to depict the same or similar elements, features, and structures.

### MODE FOR INVENTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

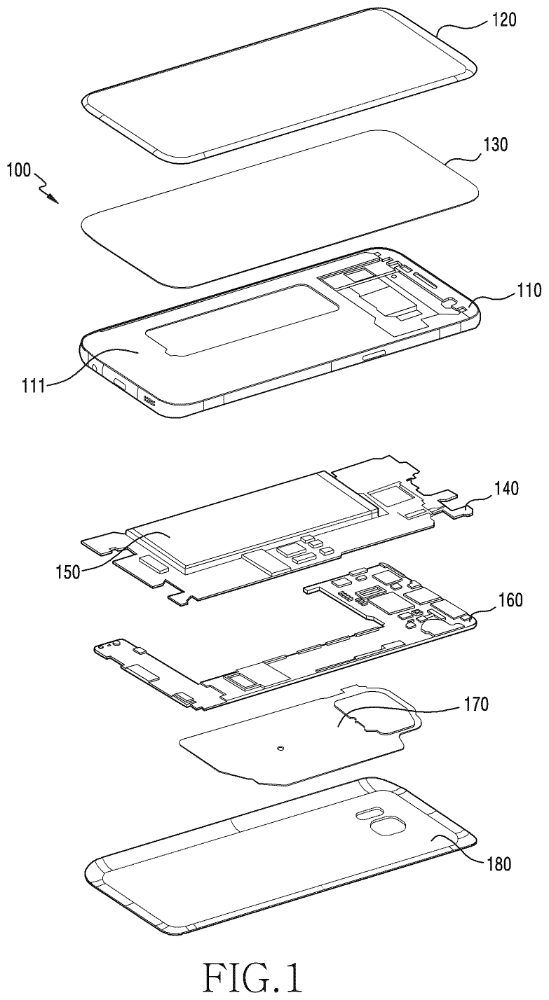

FIG. 1 is an exploded perspective view of an electronic device according to an embodiment of the disclosure.

Referring to FIG. 1, an electronic device 100 may include a plate 110 (e.g., side bezel structure), a first support member 111 (e.g., bracket or support structure), a front plate 120 (e.g., front cover), a display 130, a substrate 140 (e.g., printed circuit board (PCB), flexible PCB (FPCB), or rigid-flexible PCB (RFPCB)), a battery 150, a second support member 160 (e.g., rear case), an antenna 170, and a rear plate 180 (e.g., rear cover). In some embodiments, the electronic device 100 may omit at least one (e.g., first support member 111 or second support member 160) of the components or may additionally include other components.

The first support member 111 may be arranged inside the electronic device 100 and connected to the plate 110, or may be formed integrally with the plate 110. The first support member 111 may be formed of, for example, a metal material and/or a non-metallic (e.g., polymer) material. The display 130 may be coupled to one surface of the first support member 111, and the substrate 140 may be coupled to the other surface of the first support member 111. The substrate 140 may be equipped with a processor, memory, and/or an interface. The processor may include, for example, one or more of a central processing unit, an application processor, a graphics processing unit, an image signal processor, a sensor hub processor, or a communication processor.

The memory may include, for example, volatile memory or non-volatile memory.

The interface may include, for example, a high definition multimedia interface (HDMI), a universal serial bus (USB) interface, a secure digital (SD) card interface, and/or an audio interface. The interface may electrically or physically connect the electronic device 100 to an external electronic device, and may include, for example, a USB connector, an SD card/multimedia card (MMC) connector, or an audio connector.

The battery 150, which is a device for supplying power to at least one component of the electronic device 100, may include, for example, a non-rechargeable primary battery, a rechargeable secondary battery, or a fuel cell. At least a portion of the battery 150 may be disposed substantially on the same plane as, for example, the substrate 140. The battery 150 may be integrally arranged within the electronic device 100. In another embodiment, the battery 150 may be arranged detachably from the electronic device 100 as well.

The antenna 170 may be arranged between the rear plate 180 and the battery 150. The antenna 170 may include, for example, a near field communication (NFC) antenna, a wireless charging antenna, and/or a magnetic secure transmission (MST) antenna. The antenna 170 may, for example, perform short-range communication with an external device or wirelessly transmit and receive power required for charging. In another embodiment, an antenna structure may be formed by part of the side bezel structure 110 and/or the first support member 111 or a combination thereof.

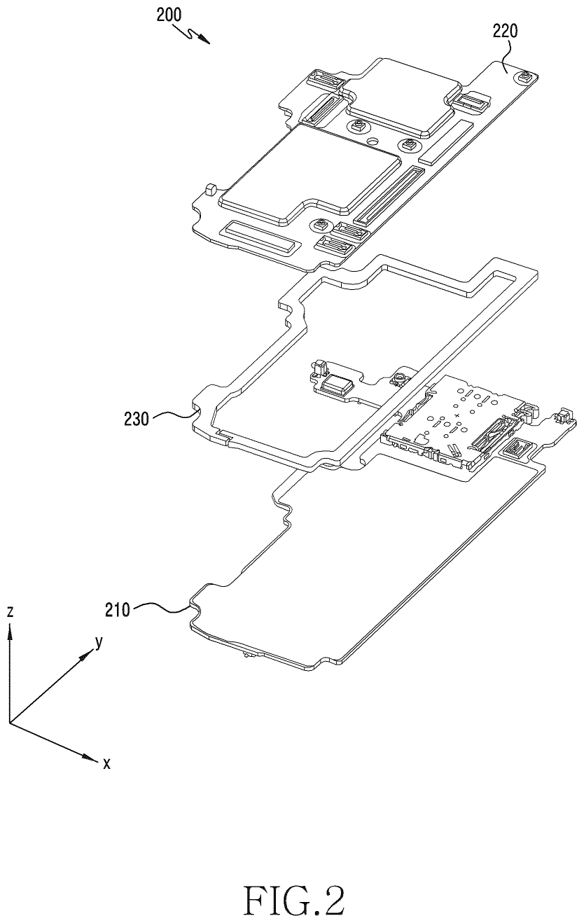

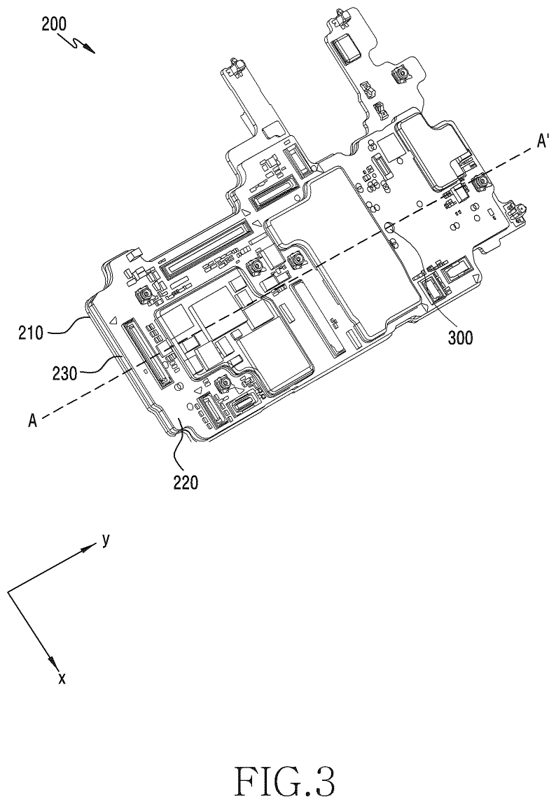

FIG. 2 is an exploded perspective view of a printed circuit board assembly according to an embodiment of the disclosure. FIG. 3 is a perspective view of the printed circuit board assembly according to an embodiment of the disclosure.

According to an embodiment of the disclosure, a printed circuit board assembly 200 may include a first printed circuit board 210, a second printed circuit board 220, and a first interposer circuit 230. For example, the printed circuit board assembly 200 may be arranged inside the electronic device 100 of FIG. 1. For example, the printed circuit board assembly 200 may be arranged between the plate 110 of FIG. 1 and the second support member 160 of FIG. 1. For example, the printed circuit board assembly 200 may be arranged between the first support member 111 of FIG. 1 and the second support member 160 of FIG. 1. For example, the first printed circuit board 210 and the second printed circuit board 220 may be included in the substrate 140 of FIG. 1.

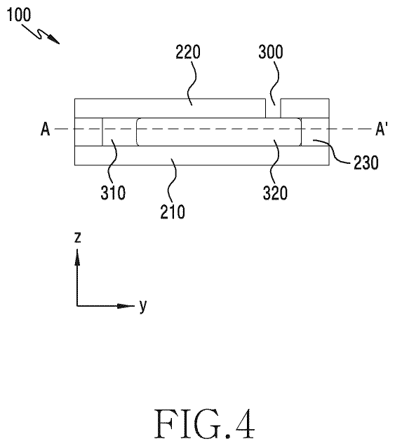

According to an embodiment of the disclosure, referring to FIG. 2, the first interposer circuit 230 may be arranged between the first printed circuit board 210 and the second printed circuit board 220. For example, the first interposer circuit 230 may be arranged to at least partially surround a space between the first printed circuit board 210 and the second printed circuit board 220. For example, the first interposer circuit 230 may form a side portion of the printed circuit board assembly 200. For example, an internal space (e.g., first space 310 of FIG. 4) of the printed circuit board assembly 200 may be formed by the first interposer circuit 230, the first printed circuit board 210, and the second printed circuit board 220. For example, the first interposer circuit 230 may support the first printed circuit board 210 and the second printed circuit board 220.

According to an embodiment of the disclosure, referring to FIG. 2, the first printed circuit board 210 and the second printed circuit board 220 may be coupled to the first interposer circuit 230. For example, the first printed circuit board 210 may be attached to one surface, facing a −z-axis direction, of the first interposer circuit 230. For example, one surface of the first interposer circuit 230 may be attached on the first printed circuit board 210 along an edge portion of the first printed circuit board 210. For example, the second printed circuit board 220 may be attached to the other surface, facing a +z-axis direction, of the first interposer circuit 230. For example, the other surface of the first interposer circuit 230 may be attached on the second printed circuit board 220 along an edge portion of the second printed circuit board 220.

According to an embodiment of the disclosure, the first interposer circuit 230 may electrically connect the first printed circuit board 210 to the second printed circuit board 220. For example, the first interposer circuit 230 may electrically connect electronic components disposed on the first printed circuit board 210 to electronic components disposed on the second printed circuit board 220. For example, the first interposer circuit 230 may transfer signals between the electronic components of the first printed circuit board 210 and the electronic components of the second printed circuit board 220. For example, the first interposer circuit 230 may serve as a grounding portion and prevent residual current, leakage current, static electricity, noise, and/or electromagnetic interference (EMI) generated by the first printed circuit board 210 and/or the second printed circuit board 220.

According to an embodiment of the disclosure, the first interposer circuit 230 may shield electromagnetic waves. For example, the first interposer circuit 230 may shield electromagnetic waves generated by electronic components arranged outside the printed circuit board assembly 200 wherein electronic components arranged inside the printed circuit board assembly 200 are not interfered by the electromagnetic waves generated by electronic components arranged outside the printed circuit board assembly 200. For example, the first interposer circuit 230 may shield noise generated by the electronic components inside the printed circuit board assembly 200 wherein the noise generated by the electronic components inside the printed circuit board assembly 200 does not affect the electronic components outside the printed circuit board assembly 200.

According to an embodiment of the disclosure, the first interposer circuit 230 may be formed of a material that may conduct a heat generated from a plurality of electronic components inside the printed circuit board assembly 200, to the outside of the printed circuit board assembly 200. According to an embodiment, the heat inside the printed circuit board assembly 200 may be dissipated to the outside of the printed circuit board assembly 200, by a thermally conductive material 320 injected into the inside of the printed circuit board assembly 200 of FIG. 4, which will be described later.

FIG. 4 is a cross-sectional view taken along line A-A′ of FIG. 3 according to an embodiment of the disclosure. For example, FIG. 4 may be a diagram illustrating the thermally conductive material 320 injected into the inside of the printed circuit board assembly 200.

According to an embodiment of the disclosure, referring to FIG. 4, the thermally conductive material 320 may be injected into a first space 310 of the printed circuit board assembly 200 through a first hole 300. For example, the thermally conductive material 320 may be injected into the first space 310 through the first hole 300 and be arranged within the first space 310. For example, the first hole 300 may be formed in the second printed circuit board 220. For example, the first hole 300 may be formed to penetrate one surface, facing a +z-axis direction, of the second printed circuit board 220 and the other surface, opposite to one surface, of the second printed circuit board 220. For example, the first hole 300 may be formed in a portion, not overlapping the first interposer circuit 230, of the second printed circuit board 220, when viewing the second printed circuit board 220 in a direction perpendicular to one surface, facing the +z-axis direction, of the second printed circuit board 220.

According to an embodiment of the disclosure, the first space 310 may include an internal space of the printed circuit board assembly 200. For example, the first space 310 may include a space surrounded by the first printed circuit board 210, the second printed circuit board 220, and the first interposer circuit 230. For example, the first space 310 may be formed by arranging the first interposer circuit 230 to at least partially surround a space between the first printed circuit board 210 and the second printed circuit board 220.

According to an embodiment of the disclosure, the thermally conductive material 320 may fill within the first space 310. For example, the thermally conductive material 320 may allow a heat generated by electronic components mounted within the first space 310, a heat generated by electronic components disposed on the first printed circuit board 210, and/or a heat generated by electronic components disposed on the second printed circuit board 220 to be dispersed within the first space 310. For example, the thermally conductive material 320 may fill within the first space 310, whereby the thermally conductive material 320 may support the first printed circuit board 210 and the second printed circuit board 220 or prevent foreign substances from being introduced into the first space 310. For example, the thermal conductive material 320 may improve the stability of signal transfer between the electronic components within the first space 310 or prevent the electronic components within the first space 310 from being interfered by electromagnetic waves outside the first space 310.

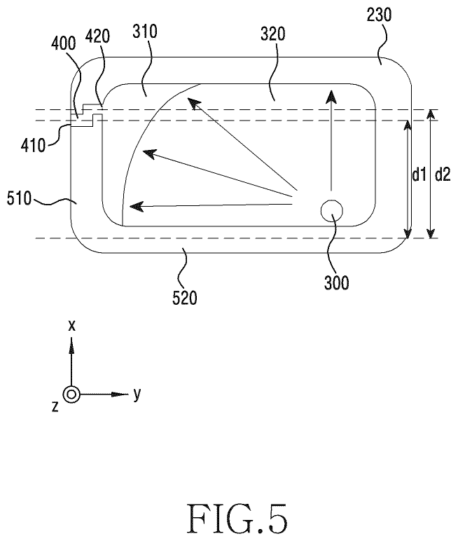

According to an embodiment of the disclosure, for example, the thermal conductive material 320 may include a liquid filler. For example, as the liquid thermal conductive material 320 is injected into the first space 310, the pressure of air within the first space 310 may increase. For example, as the pressure of air within the first space 310 increases, electronic components within the first space 310 may be damaged. According to an embodiment, a ventilation path (e.g., first ventilation path 400 of FIG. 5) may be formed in the printed circuit board assembly 200 and may discharge the air within the first space 310 to the outside of the first space 310 wherein the pressure of the air within the first space 310 is not increased by the liquid thermally conductive material 320. The ventilation path (e.g., first ventilation path 400 of FIG. 5) will be described in detail in FIG. 5, which will be described later.

FIG. 5 is a diagram illustrating the positions of a first end and a second end of a first ventilation path according to an embodiment of the disclosure.

According to an embodiment of the disclosure, the printed circuit board assembly 200 may include a first ventilation path 400 formed wherein a fluid within the first space 310 may move to the outside of the printed circuit board assembly 200. For example, while the liquid thermally conductive material 320 is injected into the first space 310, air within the first space 310 may move to the outside of the printed circuit board assembly 200 through the first ventilation path 400, and the pressure of the air within the first space 310 may not increase.

According to an embodiment of the disclosure, when the first ventilation path 400 is formed in at least one of the first printed circuit board 210 or the second printed circuit board 220, the first ventilation path 400 should be formed in a position as far away as possible from the first hole 300, but there is a limitation in determining the position of the first ventilation path 400 since electronic components are mounted on the first printed circuit board 210 and the second printed circuit board 220. The first ventilation path 400 may be formed in the first interposer circuit 230 wherein the first ventilation path 400 may discharge the air within the first space 310 in a position far from the first hole 300 regardless of the positions of the mounted electronic components.

According to an embodiment of the disclosure, the first ventilation path 400 may be formed in any one of a plurality of portions of the first interposer circuit 230. For example, the first ventilation path 400 may be formed in a first portion 510 of the first interposer circuit 230. For example, the first ventilation path 400 may be formed in the first portion 510 positioned at the farthest distance from the first hole 300 among the plurality of portions of the first interposer circuit 230. For example, the first portion 510 may include a segment portion that divides the first portion 510 into two portions. For example, at least a portion of a gap formed in the segment portion may be covered by the first printed circuit board 210 and the second printed circuit board 220, whereby the first ventilation path 400 may be formed. According to an embodiment, the plurality of portions of the first interposer circuit 230 may be referred to as a plurality of side portions, and the first portion 510 may be referred to as a first side portion.

According to an embodiment of the disclosure, the first ventilation path 400 may include a first end 410 and a second end 420. For example, the first ventilation path 400 may connect the first end 410 to the second end 420. For example, the first end 410 may be formed at an outer side of the first portion 510. For example, the outer side of the first portion 510 may face the outside of the printed circuit board assembly 200. For example, the first end 410 may be formed on an outer surface of the first interposer circuit 230. For example, the second end 420 may be formed at an inner side of the first portion 510. For example, the inner side of the first portion 510 may face the inside of the printed circuit board assembly 200. For example, the inner side of the first portion 510 may face the first space 310. For example, the second end 420 may be formed on an inner surface of the first interposer circuit 230.

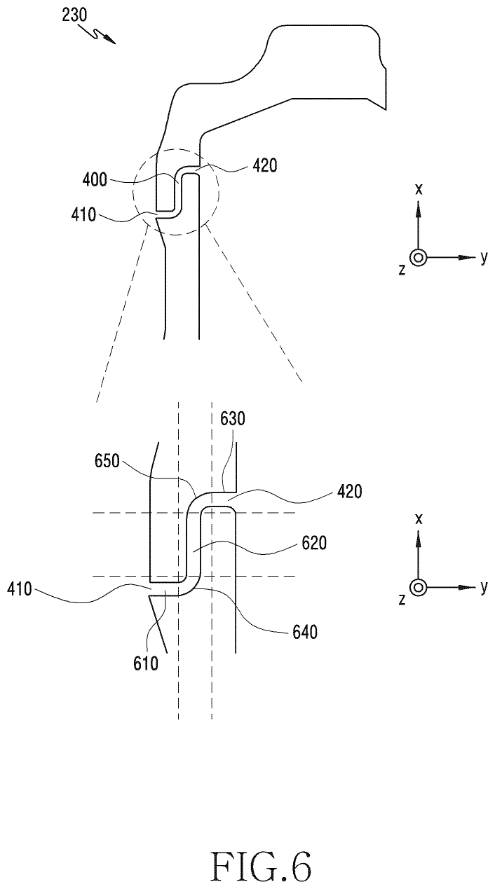

According to an embodiment, the first ventilation path 400 connecting the first end 410 to the second end 420 may be formed in a shape for shielding noise generated by electronic components arranged in the first space 310 of the printed circuit board assembly 200 or shielding electromagnetic waves generated by electronic components outside the printed circuit board assembly 200. The shape of the first ventilation path 400 will be described in detail in FIG. 6, which will be described later.

According to an embodiment of the disclosure, a position where a fluid in the first space 310 is discharged to the first end 410 may be different from a position where a fluid is introduced to the second end 420. For example, when looking at the first ventilation path 400 in a +z-axis direction, a central axis of the first end 410 may not overlap a central axis of the second end 420. For example, when looking at the first ventilation path 400 in the +z-axis direction, the center axis of the first end 410 may be formed to be parallel to the center axis of the second end 420.

According to an embodiment of the disclosure, the first interposer circuit 230 may include a second portion 520 extending from the first portion 510 and substantially perpendicular to the first portion 510. The first portion 510 may include one end extending in a first direction (e.g., x-axis direction). The second portion 520 may be formed to extend from one end of the first portion 510 in a second direction (e.g., y-axis direction) different from the first direction. Although the direction in which the first portion 510 extends and the direction in which the second portion 520 extends are illustrated as being substantially perpendicular to each other in FIG. 5, the disclosure is not limited thereto. According to an embodiment, a distance (d1) between one end of the second portion 520 and the central axis of the first end 410 may be different from a distance (d2) between one end of the second portion 520 and the central axis of the second end 420. For example, the distance (d1) between one end of the second portion 520 and the central axis of the first end 410 may be less than the distance (d2) between one end of the second portion 520 and the central axis of the second end 420. However, the disclosure is not limited to FIG. 5, and the distances d1 and d2 may be appropriately changed and designed.

According to an embodiment of the disclosure, the length of the first ventilation path 400 connecting the first end 410 to the second end 420 may be greater than the width of a portion of the first interposer circuit 230 in which the first ventilation path 400 is formed. For example, the widths of the plurality of portions of the first interposer circuit 230 may be formed differently from each other, but the width of the portion in which the first ventilation path 400 is formed among the plurality of portions of the first interposer circuit 230 may be less than the length of the first ventilation path 400.

According to an embodiment of the disclosure, the first end 410 may be formed in the first portion 510 of the first interposer circuit 230 toward a first axis (e.g., −y axis) direction of facing the outside of the printed circuit board assembly 200. According to an embodiment, the second end 420 may be formed in the first portion 510 of the first interposer circuit 230 toward the first space 310. For example, the position of the first end 410 on a second axis (e.g., +x axis) substantially perpendicular to the first axis may be different from the position of the second end 420 on the second axis.

According to an embodiment of the disclosure, the first ventilation path 400 connecting the first end 410 to the second end 420 may be formed not perpendicular to the first portion 510. For example, the first ventilation path 400 may be formed not parallel to the second portion 520. For example, the first ventilation path 400 may be formed not parallel to the second portion 520, whereby electromagnetic waves generated by electronic components arranged outside the printed circuit board assembly 200 may be shielded by the first ventilation path 400.

FIG. 6 is a diagram illustrating the shape of a first ventilation path according to an embodiment of the disclosure.

According to an embodiment of the disclosure, the first ventilation path 400 may be formed to include at least one bend portion and shield electromagnetic waves introduced into the inside of the first ventilation path 400. For example, the first ventilation path 400 may include a first portion 610, a second portion 620, a third portion 630, a first bend portion 640, and a second bend portion 650.

According to an embodiment of the disclosure, referring to FIG. 6, the first portion 610 may include a portion extending in a third direction from the first end 410 to the first bend portion 640. For example, the third direction may include a direction of facing the first space 310. For example, the third direction may include a direction substantially parallel to a +y axis. According to an embodiment, the first bend portion 640 may be positioned between the first portion 610 and the second portion 620. For example, the first bend portion 640 may include a portion connecting the first portion 610 to the second portion 620. For example, the first bend portion 640 may include a curved portion. For example, the first portion 610 may extend from one side of the first bend portion 640, and the second portion 620 may extend from the other side of the first bend portion 640.

According to an embodiment of the disclosure, referring to FIG. 6, the second portion 620 may include a portion extending in a fourth direction from the first bend portion 640 to the second bend portion 650. For example, the fourth direction may include a direction perpendicular to the first portion 610. For example, the fourth direction may include a direction parallel to a +x axis. According to an embodiment, the second bend portion 650 may be positioned between the second portion 620 and the third portion 630. For example, the second bend portion 650 may include a portion connecting the second portion 620 to the third portion 630. For example, the second bend portion 650 may include a curved portion. For example, the second portion 620 may be connected to one side of the second bend portion 650, and the third portion 630 may extend from the other side of the second bend portion 650.

According to an embodiment of the disclosure, referring to FIG. 6, the third portion 630 may include a portion extending in a fifth direction from the second bend portion 650 to the second end 420. For example, the fifth direction may include a direction perpendicular to the fourth direction. For example, the fifth direction may include a direction of facing the first space 310. For example, the fifth direction may include a direction parallel to the +y-axis. The shapes of the first bend portion 640 and the second bend portion 650 are not limited to the curved shape, and the first bend portion 640 may be deformed within a range for connecting the first portion 610 to the second portion 620, and the second bend portion 650 may be deformed within a range for connecting the second portion 620 to the third portion 630.

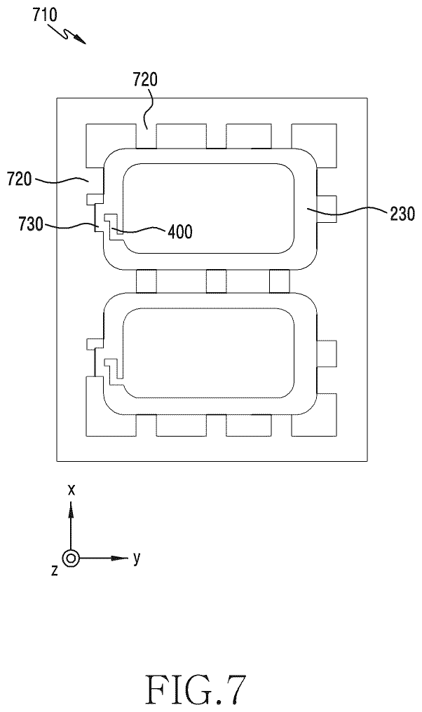

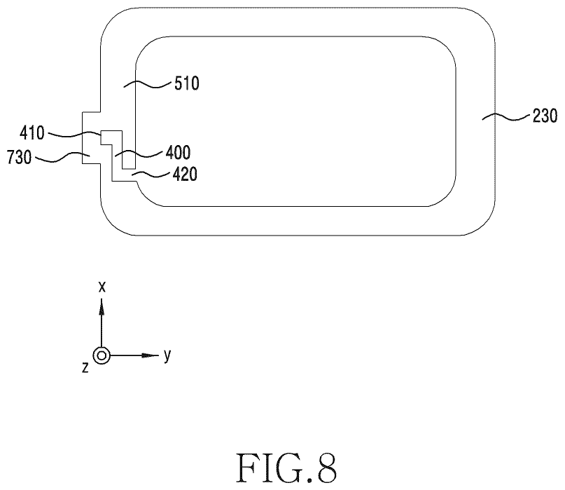

FIG. 7 is a diagram illustrating an example of a first kit formed by coupling a first interposer circuit to a first bridge portion according to an embodiment of the disclosure. FIG. 8 is a diagram illustrating an example of the first interposer circuit in which the first bridge portion is cut off according to an embodiment of the disclosure.

According to an embodiment of the disclosure, referring to FIG. 7, a first kit 710 may include the first interposer circuit 230 and a first bridge portion 720. For example, the first interposer circuit 230 may be manufactured in a state of being connected to the first bridge portion 720 in the manufacturing process of the printed circuit board assembly 200. For example, referring to FIG. 8, by cutting off the first bridge portion 720 of the first kit 710, the single first interposer circuit 230 may be formed.

According to an embodiment of the disclosure, referring to FIG. 8, the first interposer circuit 230 may include a connection portion 730 before the first interposer circuit 230 is arranged between the first printed circuit board 210 and the second printed circuit board 220. For example, the connection portion 730 may include a part of the first bridge portion 720. For example, the connection portion 730 may be positioned between the first ventilation path 400 and the first bridge portion 720. For example, the connection portion 730 may include a portion surrounding the first end 410 of the first ventilation path 400.

According to an embodiment of the disclosure, for example, part of the first portion 510 of the first interposer circuit 230 and the remnant thereof may be formed to be separated by the first ventilation path 400. For example, in the process of forming the single first interposer circuit 230, the first portion 510 of the first interposer circuit 230 may be bent or damaged when the connection portion 730 formed to surround the first end 410 of the first ventilation path 400 is cut off. For example, the connection portion 730 may guide an attachment position of the first interposer circuit 230 in the process of attaching the first interposer circuit 230 to the second printed circuit board 220.

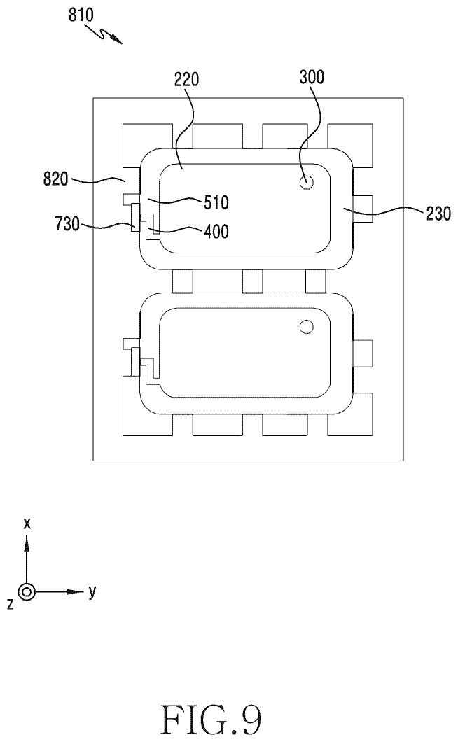

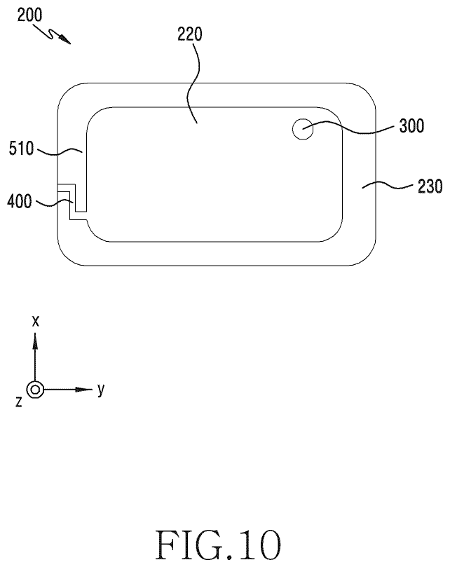

FIG. 9 is a diagram illustrating an example in which a first interposer circuit is coupled to a second printed circuit board coupled to a second bridge portion according to an embodiment of the disclosure. FIG. 10 is a diagram illustrating an example in which the second bridge portion is cut off in a state in which the first interposer circuit is coupled to the second printed circuit board of FIG. 9 according to an embodiment of the disclosure.

According to an embodiment of the disclosure, referring to FIG. 9, a second kit 810 may include the second printed circuit board 220 and a second bridge portion 820. For example, the second printed circuit board 220 may be manufactured in a state of being connected to the second bridge portion 820 in the manufacturing process of the printed circuit board assembly 200. For example, referring to FIG. 10, in a state in which the first interposer circuit 230 is attached on the second printed circuit board 220, the second bridge portion 820 of the second kit 810 may be cut off, whereby the printed circuit board assembly 200 may be formed.

According to an embodiment of the disclosure, referring to FIG. 9, the connection portion 730 of the first interposer circuit 230 may be arranged to overlap the second bridge portion 820 of the second kit 810. For example, the connection portion 730 may guide the first interposer circuit 230 to be attached on the second printed circuit board 220. For example, the connection portion 730 may be formed to surround part of the first ventilation path 400 of the first interposer circuit 230 wherein the first portion 510 of the first interposer circuit 230 is not bent or damaged by the first ventilation path 400 in the process of attaching the first interposer circuit 230 on the second printed circuit board 220.

According to an embodiment of the disclosure, referring to FIG. 10, in a state where the first interposer circuit 230 is attached on the second printed circuit board 220, the connection portion 730 may be cut off together with the second bridge portion 820. In a state where the connection portion 730 and the second bridge portion 820 are cut off, the first printed circuit board 210 may be attached on the first interposer circuit 230, whereby the printed circuit board assembly 200 may be manufactured.

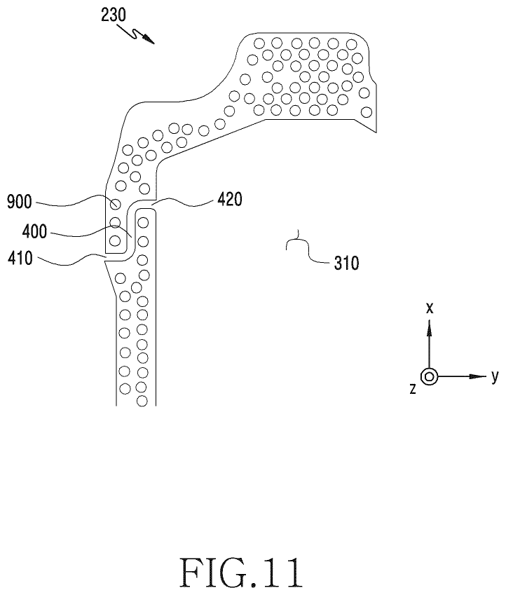

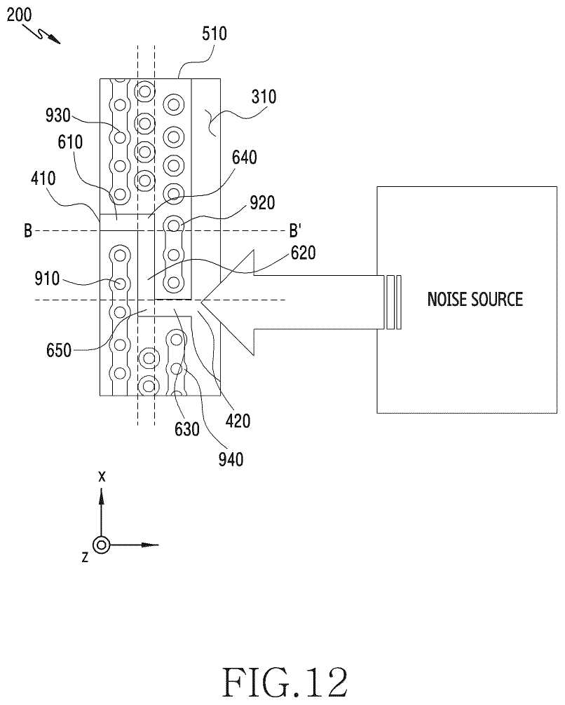

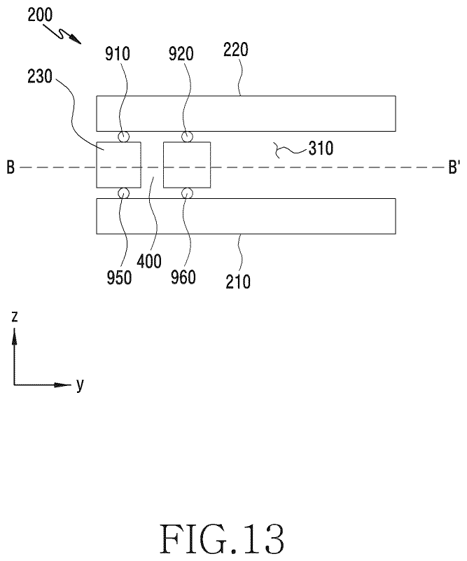

FIG. 11 is a diagram illustrating an example of a plurality of conductors formed on a first interposer circuit according to an embodiment of the disclosure. FIG. 12 is a diagram illustrating an example of a grounding pad composed of a plurality of conductors according to an embodiment of the disclosure. FIG. 13 is a cross-sectional view of a section taken along line B-B′ of FIG. 12 according to an embodiment of the disclosure.

According to an embodiment of the disclosure, referring to FIG. 11, the first interposer circuit 230 may include a plurality of conductors 900. For example, some of the plurality of conductors 900 may be disposed on one surface, facing a +z-axis direction, of the first interposer circuit 230. For example, some others of the plurality of conductors 900 may be disposed on the other surface, facing a −z-axis direction, of the first interposer circuit 230.

According to an embodiment of the disclosure, for example, some of the plurality of conductors 900 may transmit and receive signals between electronic components disposed on the first printed circuit board 210 and electronic components disposed on the second printed circuit board 220. For example, the printed circuit board assembly 200 may include a grounding portion, and some others of the plurality of conductors 900 may transfer residual current, or/and static electricity, generated by the printed circuit board assembly 200, to the grounding portion of the printed circuit board assembly 200.

According to an embodiment of the disclosure, referring to FIG. 11, some of the plurality of conductors 900 may be arranged in positions adjacent to the first ventilation path 400. For example, some of the plurality of conductors 900 may be arranged around the first ventilation path 400. For example, some of the plurality of conductors 900 may be disposed on the first interposer circuit 230 along the first ventilation path 400. For example, some of the plurality of conductors 900 may be arranged along the first ventilation path 400, whereby some of the plurality of conductors 900 may effectively transfer static electricity introduced into the first ventilation path 400 to the grounding portion of the printed circuit board assembly 200. For example, the conductors arranged around the first ventilation path 400 among the plurality of conductors 900 may be electrically connected to the grounding portion of the first printed circuit board 210 and/or the second printed circuit board 220 of the printed circuit board assembly 200. For example, noise generated from the inside of the first space 310 of the first interposer circuit 230 and/or noise generated from the outside of the printed circuit board assembly 200 may be grounded through the grounding portion of the first printed circuit board 210 and/or the second printed circuit board 220 by the conductors arranged around the first ventilation path 400.

According to an embodiment of the disclosure, referring to FIG. 12, the printed circuit board assembly 200 may include a plurality of grounding pads including at least one conductor among the plurality of conductors 900. For example, the plurality of grounding pads may include a first grounding pad 910, a second grounding pad 920, a third grounding pad 930, and a fourth grounding pad 940. According to an embodiment, the plurality of grounding pads may be disposed on the first interposer circuit 230 along the first ventilation path 400. For example, when the printed circuit board assembly 200 is viewed from above (e.g., z-axis direction), the first grounding pad 910 may be arranged between an outer side of the first portion 510 of the first interposer circuit 230 and the second portion 620 of the first ventilation path 400. For example, when the printed circuit board assembly 200 is viewed from above (e.g., z-axis direction), the second grounding pad 920 may be arranged between the second portion 620 of the first ventilation path 400 and an inner side of the first portion 510 of the first interposer circuit 230. For example, when the printed circuit board assembly 200 is viewed from above (e.g., z-axis direction), the first portion 610 of the first ventilation path 400 may be positioned between the first grounding pad 910 and the third grounding pad 930. For example, when the printed circuit board assembly 200 is viewed from above (e.g., z-axis direction), the third portion 630 of the first ventilation path 400 may be positioned between the second grounding pad 920 and the fourth grounding pad 940.

According to an embodiment of the disclosure, electromagnetic waves introduced into the first ventilation path 400 through the second end 420 may be transferred to the grounding portion of the printed circuit board assembly 200 by the first grounding pad 910, the second grounding pad 920, the third grounding pad 930 or/and the fourth grounding pad 940 arranged along the first ventilation path 400 among the plurality of grounding pads. For example, by arranging the plurality of grounding pads in positions adjacent to the first ventilation path 400, noise emitted from the first space 310 to the outside of the printed circuit board assembly 200 may be transferred to the grounding portion of the printed circuit board assembly 200.

According to an embodiment of the disclosure, referring to FIG. 13, the plurality of grounding pads may further include a fifth grounding pad 950 and a sixth grounding pad 960. According to an embodiment, the first grounding pad 910 and the second grounding pad 920 may be arranged between the second printed circuit board 220 and one surface, facing a +z-axis direction, of the first interposer circuit 230. For example, the first grounding pad 910 and the second grounding pad 920 may transfer signals generated by electronic components provided on the second printed circuit board 220, to the grounding portion of the printed circuit board assembly 200. According to an embodiment, the fifth grounding pad 950 and the sixth grounding pad 960 may be arranged between the first printed circuit board 210 and the other surface, facing a −z-axis direction, of the first interposer circuit 230. For example, the fifth grounding pad 950 and the sixth grounding pad 960 may transfer signals generated by electronic components provided on the first printed circuit board 210, to the grounding portion of the printed circuit board assembly 200.

According to an embodiment of the disclosure, the first grounding pad 910 may be electrically connected to the fifth grounding pad 950 through a conductive via formed in the first interposer circuit 230. According to an embodiment, the second grounding pad 920 may be electrically connected to the sixth grounding pad 960 through a conductive via formed in the first interposer circuit 230.

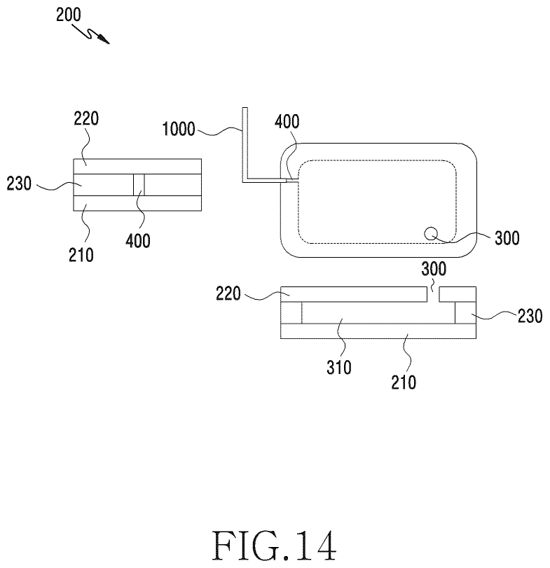

FIG. 14 is a diagram illustrating an example of a pipe connected to a first ventilation path according to an embodiment of the disclosure.

According to an embodiment of the disclosure, a pipe 1000 may be connected to the first ventilation path 400 of the printed circuit board assembly 200. For example, when the vacuum-state pipe 1000 is connected to the first ventilation path 400, air within the first space 310 having a relatively higher pressure than the inside of the pipe 1000 may move to the outside of the printed circuit board assembly 200 along the pipe 1000. According to an embodiment, as the air within the first space 310 inside the printed circuit board assembly 200 moves to the outside of the printed circuit board assembly 200 along the pipe 1000, the liquid thermally conductive material 320 may be effectively filled in the first space 310 through the first hole 300.

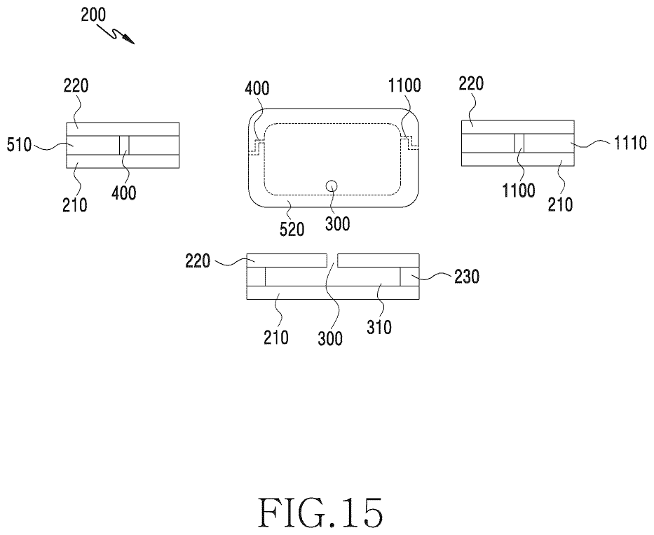

FIG. 15 is a diagram illustrating an example of a second ventilation path formed in a third portion of a first interposer circuit according to an embodiment of the disclosure.

According to an embodiment of the disclosure, the plurality of portions of the first interposer circuit 230 may further include a third portion 1110. For example, the third portion 1110 may include a portion extending from the second portion 520 and perpendicular to the second portion 520. For example, the third portion 1110 may include a portion opposite to the first portion 510. For example, the third portion 1110 may include a portion formed parallel to the first portion 510. According to an embodiment, the third portion 1110 may be referred to as a third side portion.

According to an embodiment of the disclosure, the printed circuit board assembly 200 may further include a second ventilation path 1100. For example, the second ventilation path 1100 may be formed in the third portion 1110 of the first interposer circuit 230. For example, the second ventilation path 1100 may be formed identically to the first ventilation path 400 of FIGS. 5 to 14. According to an embodiment, when the second ventilation path 1100 is formed in the first interposer circuit 230 together with the first ventilation path 400, air inside the printed circuit board assembly 200 may be discharged more effectively to the outside of the printed circuit board assembly 200 than when only the first ventilation path 400 is formed in the first interposer circuit 230.

According to an embodiment of the disclosure, referring to FIG. 15, the first hole 300 may be formed in the second printed circuit board 220 wherein a distance from the first ventilation path 400 to the first hole 300 is the same as a distance from the second ventilation path 1100 to the first hole 300. For example, when the first hole 300 is formed in a position closer to the second ventilation path 1100 than to the first ventilation path 400, the liquid thermally conductive material 320 filled in the first space 310 through the first hole 300 may be discharged to the outside of the printed circuit board assembly 200 through the second ventilation path 1100 before being completely filled in the first space 310. For example, when the position of the first hole 300 is designed wherein a distance between the first hole 300 and the first ventilation path 400 is the same as a distance between the first hole 300 and the second ventilation path 1100, the thermally conductive material 320 may fill and evenly distributed in the first space 310.

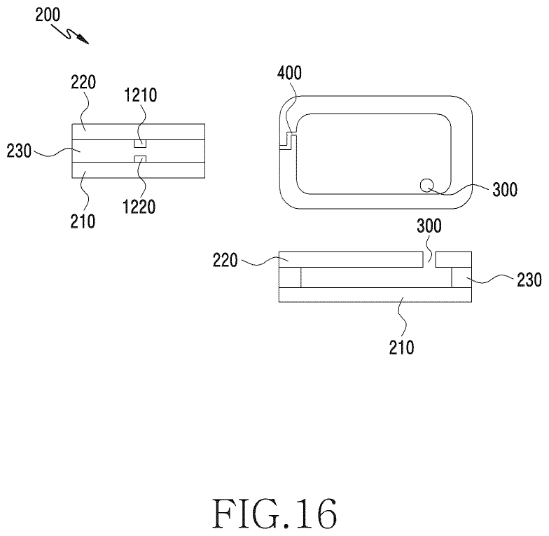

FIG. 16 is a diagram illustrating an example of a first ventilation path formed by a first groove and a second groove according to an embodiment of the disclosure.

According to an embodiment of the disclosure, the first interposer circuit 230 may include a first groove 1210 and a second groove 1220. For example, the first groove 1210 may be formed in one surface, facing a +z-axis direction, of the first portion 510 of the first interposer circuit 230. For example, the first groove 1210 may include a recess formed in a −z-axis direction. For example, the second groove 1220 may be formed in the other surface, facing the-z-axis direction, of the first portion 510 of the first interposer circuit 230. For example, the second groove 1220 may include a recess formed in the +z-axis direction.

According to an embodiment of the disclosure, the first ventilation path 400 may be divided into two paths by the first groove 1210 and the second groove 1220. For example, one ventilation path may be formed by the first groove 1210 and the second printed circuit board 220 arranged to cover the first groove 1210, and the other ventilation path may be formed by the second groove 1220 and the first printed circuit board 210 arranged to cover the second groove 1220. According to an embodiment, as the first ventilation path 400 is divided into two paths, the sizes of the first end 410 and the second end 420 may be reduced and thus the speed of air moving through the two paths may be increased.

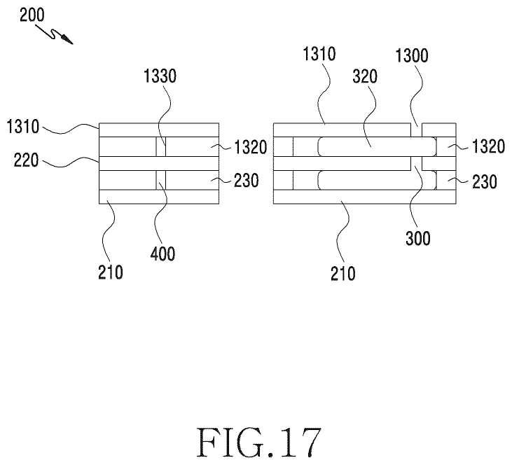

FIG. 17 is a diagram illustrating an example of a third ventilation path formed in a second interposer circuit according to an embodiment of the disclosure.

According to an embodiment of the disclosure, the printed circuit board assembly 200 may further include a third printed circuit board 1310 and a second interposer circuit 1320. For example, the second interposer circuit 1320 may be laminated on the second printed circuit board 220. For example, the second interposer circuit 1320 may be arranged to at least partially surround a space between the second printed circuit board 220 and the third printed circuit board 1310.

According to an embodiment of the disclosure, the printed circuit board assembly 200 may further include a third ventilation path 1330. For example, the third ventilation path 1330 may be surrounded by the second printed circuit board 220, the third printed circuit board 1310, and the second interposer circuit 1320. The shape and/or position of the third ventilation path 1330 may correspond to, but is not limited to, the first ventilation path 400 of FIGS. 5 to 14.

According to an embodiment of the disclosure, a second hole 1300 may be formed in the third printed circuit board 1310. For example, the thermally conductive material 320 may be injected into the inside of the printed circuit board assembly 200 through the second hole 1300. According to an embodiment, the second hole 1300 may be formed in a position corresponding to the first hole 300, but is not limited thereto. For example, the thermally conductive material 320 injected through the second hole 1300 may fill in the entire first space 310 through the first hole 300 and then fill in a space surrounded by the second printed circuit board 220, the third printed circuit board 1310, and the second interposer circuit 1320.

According to an embodiment of the disclosure, while the thermal conductive material 320 fills inside the printed circuit board assembly 200, air inside the printed circuit board assembly 200 may be discharged to the outside of the printed circuit board assembly 200 through the first ventilation path 400 and the third ventilation path 1330.

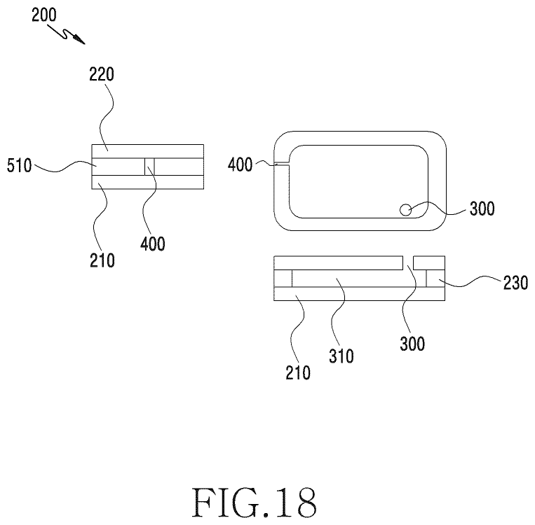

FIG. 18 is a diagram illustrating an example of a first ventilation path according to an embodiment of the disclosure.

According to an embodiment of the disclosure, the first ventilation path 400 of the printed circuit board assembly 200 may not include at least one bend portion. For example, the first ventilation path 400 may be formed perpendicular to the first portion 510 of the first interposer circuit 230. For example, the first ventilation path 400 may be formed parallel to the second portion 520 of the first interposer circuit 230. For example, a distance (d1) between the first end 410 and the second portion 520 of the first interposer circuit 230 may be the same as a distance (d2) between the second end 420 and the second portion 520 of the first interposer circuit 230.

According to an embodiment of the disclosure, when the first ventilation path 400 does not include at least one bend portion, a fluid in the first space 310 of the printed circuit board assembly 200 may be more easily discharged to the outside of the printed circuit board assembly 200 through the first ventilation path 400 than when the first ventilation path 400 includes at least one bend portion.

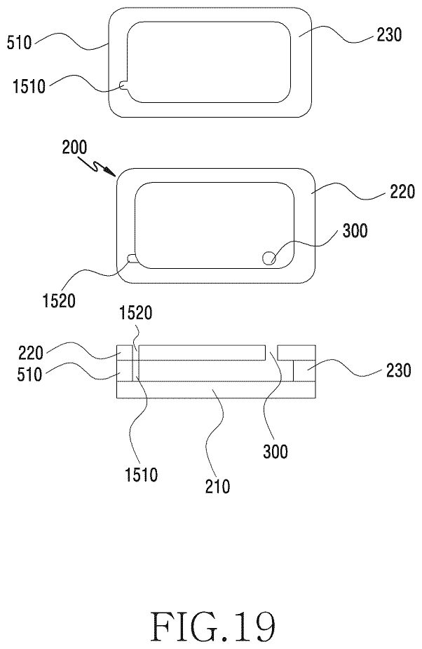

FIG. 19 is a diagram illustrating an example of a first interposer circuit including a recess according to an embodiment of the disclosure.

According to an embodiment of the disclosure, the first interposer circuit 230 may include a recess 1510. For example, the recess 1510 may be formed in the first portion 510 of the first interposer circuit 230. For example, the recess 1510 may be formed at an inner side of the first portion 510. For example, the recess 1510 may be formed concavely in a direction of facing the outside of the printed circuit board assembly 200. For example, the recess 1510 may be formed by cutting out a portion of the first portion 510.

According to an embodiment of the disclosure, the second printed circuit board 220 may include a third opening 1520. For example, the third opening 1520 may be formed to penetrate the second printed circuit board 220. For example, the third opening 1520 may be formed in a position corresponding to the recess 1510 of the first interposer circuit 230. For example, in a state in which the second printed circuit board 220 is arranged on the first interposer circuit 230, the third opening 1520 of the second printed circuit board 220 may be aligned with the recess 1510 of the first interposer circuit 230.

According to an embodiment of the disclosure, the recess 1510 and the third opening 1520 may form a ventilation path. For example, a fluid inside the printed circuit board assembly 200 may be discharged to the outside of the printed circuit board assembly 200 through the recess 1510 and the third opening 1520. For example, while the thermally conductive material 320 is injected into the inside of the printed circuit board assembly 200 through the first hole 300, the fluid inside the printed circuit board assembly 200 may be discharged to the outside of the printed circuit board assembly 200 through the recess 1510 and the third opening 1520.

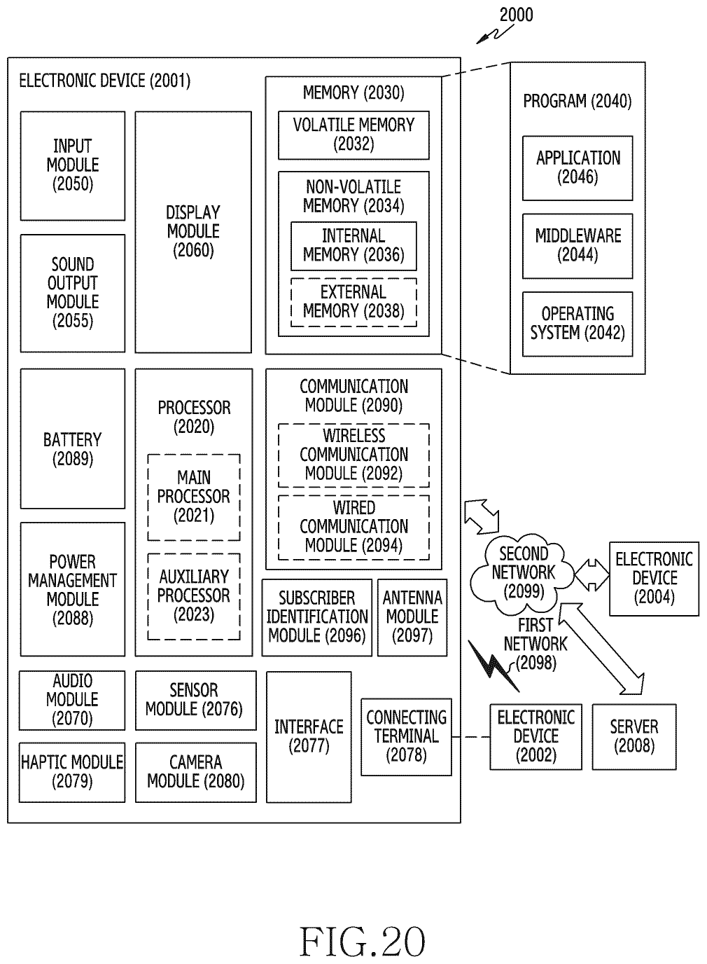

FIG. 20 is a block diagram illustrating an electronic device 2001 in a network environment 2000 according to an embodiment of the disclosure.

Referring to FIG. 20, the electronic device 2001 in the network environment 2000 may communicate with an electronic device 2002 via a first network 2098 (e.g., a short-range wireless communication network), or at least one of an electronic device 2004 or a server 2008 via a second network 2099 (e.g., a long-range wireless communication network). According to an embodiment, the electronic device 2001 may communicate with the electronic device 2004 via the server 2008. According to an embodiment, the electronic device 2001 may include a processor 2020, memory 2030, an input module 2050, a sound output module 2055, a display module 2060, an audio module 2070, a sensor module 2076, an interface 2077, a connecting terminal 2078, a haptic module 2079, a camera module 2080, a power management module 2088, a battery 2089, a communication module 2090, a subscriber identification module (SIM) 2096, or an antenna module 2097. In some embodiments, at least one of the components (e.g., the connecting terminal 2078) may be omitted from the electronic device 2001, or one or more other components may be added in the electronic device 2001. In some embodiments, some of the components (e.g., the sensor module 2076, the camera module 2080, or the antenna module 2097) may be implemented as a single component (e.g., the display module 2060).

The processor 2020 may execute, for example, software (e.g., a program 2040) to control at least one other component (e.g., a hardware or software component) of the electronic device 2001 coupled with the processor 2020, and may perform various data processing or computation. According to one embodiment, as at least part of the data processing or computation, the processor 2020 may store a command or data received from another component (e.g., the sensor module 2076 or the communication module 2090) in volatile memory 2032, process the command or the data stored in the volatile memory 2032, and store resulting data in non-volatile memory 2034. According to an embodiment, the processor 2020 may include a main processor 2021 (e.g., a central processing unit (CPU) or an application processor (AP)), or an auxiliary processor 2023 (e.g., a graphics processing unit (GPU), a neural processing unit (NPU), an image signal processor (ISP), a sensor hub processor, or a communication processor (CP)) that is operable independently from, or in conjunction with, the main processor 2021. For example, when the electronic device 2001 includes the main processor 2021 and the auxiliary processor 2023, the auxiliary processor 2023 may be adapted to consume less power than the main processor 2021, or to be specific to a specified function. The auxiliary processor 2023 may be implemented as separate from, or as part of the main processor 2021.

The auxiliary processor 2023 may control at least some of functions or states related to at least one component (e.g., the display module 2060, the sensor module 2076, or the communication module 2090) among the components of the electronic device 2001, instead of the main processor 2021 while the main processor 2021 is in an inactive (e.g., sleep) state, or together with the main processor 2021 while the main processor 2021 is in an active state (e.g., executing an application). According to an embodiment, the auxiliary processor 2023 (e.g., an image signal processor or a communication processor) may be implemented as part of another component (e.g., the camera module 2080 or the communication module 2090) functionally related to the auxiliary processor 2023. According to an embodiment, the auxiliary processor 2023 (e.g., the neural processing unit) may include a hardware structure specified for artificial intelligence model processing. An artificial intelligence model may be generated by machine learning. Such learning may be performed, e.g., by the electronic device 2001 where the artificial intelligence is performed or via a separate server (e.g., the server 2008). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 2030 may store various data used by at least one component (e.g., the processor 2020 or the sensor module 2076) of the electronic device 2001. The various data may include, for example, software (e.g., the program 2040) and input data or output data for a command related thereto. The memory 2030 may include the volatile memory 2032 or the non-volatile memory 2034.

The program 2040 may be stored in the memory 2030 as software, and may include, for example, an operating system (OS) 2042, middleware 2044, or an application 2046.

The input module 2050 may receive a command or data to be used by another component (e.g., the processor 2020) of the electronic device 2001, from the outside (e.g., a user) of the electronic device 2001. The input module 2050 may include, for example, a microphone, a mouse, a keyboard, a key (e.g., a button), or a digital pen (e.g., a stylus pen).

The sound output module 2055 may output sound signals to the outside of the electronic device 2001. The sound output module 2055 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 2060 may visually provide information to the outside (e.g., a user) of the electronic device 2001. The display module 2060 may include, for example, a display, a hologram device, or a projector and control circuitry to control a corresponding one of the display, hologram device, and projector. According to an embodiment, the display module 2060 may include a touch sensor adapted to detect a touch, or a pressure sensor adapted to measure the intensity of force incurred by the touch.

The audio module 2070 may convert a sound into an electrical signal and vice versa. According to an embodiment, the audio module 2070 may obtain the sound via the input module 2050, or output the sound via the sound output module 2055 or a headphone of an external electronic device (e.g., an electronic device 2002) directly (e.g., wiredly) or wirelessly coupled with the electronic device 2001.

The sensor module 2076 may detect an operational state (e.g., power or temperature) of the electronic device 2001 or an environmental state (e.g., a state of a user) external to the electronic device 2001, and then generate an electrical signal or data value corresponding to the detected state. According to an embodiment, the sensor module 2076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 2077 may support one or more specified protocols to be used for the electronic device 2001 to be coupled with the external electronic device (e.g., the electronic device 2002) directly (e.g., wiredly) or wirelessly. According to an embodiment, the interface 2077 may include, for example, a high definition multimedia interface (HDMI), a universal serial bus (USB) interface, a secure digital (SD) card interface, or an audio interface.

A connecting terminal 2078 may include a connector via which the electronic device 2001 may be physically connected with the external electronic device (e.g., the electronic device 2002). According to an embodiment, the connecting terminal 2078 may include, for example, a HDMI connector, a USB connector, a SD card connector, or an audio connector (e.g., a headphone connector).

The haptic module 2079 may convert an electrical signal into a mechanical stimulus (e.g., a vibration or a movement) or electrical stimulus which may be recognized by a user via his tactile sensation or kinesthetic sensation. According to an embodiment, the haptic module 2079 may include, for example, a motor, a piezoelectric element, or an electric stimulator.

The camera module 2080 may capture a still image or moving images. According to an embodiment, the camera module 2080 may include one or more lenses, image sensors, image signal processors, or flashes.

The power management module 2088 may manage power supplied to the electronic device 2001. According to one embodiment, the power management module 2088 may be implemented as at least part of, for example, a power management integrated circuit (PMIC).

The battery 2089 may supply power to at least one component of the electronic device 2001. According to an embodiment, the battery 2089 may include, for example, a primary cell which is not rechargeable, a secondary cell which is rechargeable, or a fuel cell.

The communication module 2090 may support establishing a direct (e.g., wired) communication channel or a wireless communication channel between the electronic device 2001 and the external electronic device (e.g., the electronic device 2002, the electronic device 2004, or the server 2008) and performing communication via the established communication channel. The communication module 2090 may include one or more communication processors that are operable independently from the processor 2020 (e.g., the application processor (AP)) and supports a direct (e.g., wired) communication or a wireless communication. According to an embodiment, the communication module 2090 may include a wireless communication module 2092 (e.g., a cellular communication module, a short-range wireless communication module, or a global navigation satellite system (GNSS) communication module) or a wired communication module 2094 (e.g., a local area network (LAN) communication module or a power line communication (PLC) module). A corresponding one of these communication modules may communicate with the external electronic device via the first network 2098 (e.g., a short-range communication network, such as Bluetooth™, wireless-fidelity (Wi-Fi) direct, or infrared data association (IrDA)) or the second network 2099 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 2092 may identify and authenticate the electronic device 2001 in a communication network, such as the first network 2098 or the second network 2099, using subscriber information (e.g., international mobile subscriber identity (IMSI)) stored in the subscriber identification module 2096.

The wireless communication module 2092 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 2092 may support a high-frequency band (e.g., the millimeter wave (mmWave) band) to achieve, e.g., a high data transmission rate. The wireless communication module 2092 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 2092 may support various requirements specified in the electronic device 2001, an external electronic device (e.g., the electronic device 2004), or a network system (e.g., the second network 2099). According to an embodiment, the wireless communication module 2092 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 2097 may transmit or receive a signal or power to or from the outside (e.g., the external electronic device) of the electronic device 2001. According to an embodiment, the antenna module 2097 may include an antenna including a radiating element composed of a conductive material or a conductive pattern formed in or on a substrate (e.g., a printed circuit board (PCB)). According to an embodiment, the antenna module 2097 may include a plurality of antennas (e.g., array antennas). In such a case, at least one antenna appropriate for a communication scheme used in the communication network, such as the first network 2098 or the second network 2099, may be selected, for example, by the communication module 2090 (e.g., the wireless communication module 2092) from the plurality of antennas. The signal or the power may then be transmitted or received between the communication module 2090 and the external electronic device via the selected at least one antenna. According to an embodiment, another component (e.g., a radio frequency integrated circuit (RFIC)) other than the radiating element may be additionally formed as part of the antenna module 2097.

According to various embodiments, the antenna module 2097 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 2001 and the external electronic device 2004 via the server 2008 coupled with the second network 2099. Each of the electronic devices 2002 or 2004 may be a device of a same type as, or a different type, from the electronic device 2001. According to an embodiment, all or some of operations to be executed at the electronic device 2001 may be executed at one or more of the external electronic devices 2002 or 2004, or the server 2008. For example, if the electronic device 2001 should perform a function or a service automatically, or in response to a request from a user or another device, the electronic device 2001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 2001. The electronic device 2001 may provide the outcome, with or without further processing of the outcome, as at least part of a reply to the request. To that end, a cloud computing, distributed computing, mobile edge computing (MEC), or client-server computing technology may be used, for example. The electronic device 2001 may provide ultra low-latency services using, e.g., distributed computing or mobile edge computing. In another embodiment, the external electronic device 2004 may include an internet-of-things (IoT) device. The server 2008 may be an intelligent server using machine learning and/or a neural network. According to an embodiment, the external electronic device 2004 or the server 2008 may be included in the second network 2099. The electronic device 2001 may be applied to intelligent services (e.g., smart home, smart city, smart car, or healthcare) based on 5G communication technology or IoT-related technology.

The problem to be solved of an embodiment of the disclosure may be given as follows.

According to an embodiment of the disclosure, a printed circuit board assembly including a ventilation path formed in a side portion of an interposer wherein a pressure inside the interposer is not increased by a thermally conductive material introduced into the interposer may be provided.

According to an embodiment of the disclosure, a printed circuit board assembly including a ventilation path having a bend portion capable of shielding electromagnetic waves generated by electronic components provided inside an interposer may be provided.

According to an embodiment of the disclosure, a printed circuit board assembly may include a first printed circuit board, a second printed circuit board, a first interposer circuit at least partially surrounding a first space between the first printed circuit board and the second printed circuit board, and a thermally conductive material arranged within the first space. The first interposer circuit may have a first ventilation path through which air may move from the first space to the outside of the printed circuit board assembly when the thermally conductive material is injected into the first space through a first hole formed in the first printed circuit board. The first ventilation path may connect a first end formed at an outer side, facing the outside of the printed circuit board assembly, of a first portion of the first interposer circuit, to a second end formed at an inner side, facing the first space, of the first portion of the first interposer circuit. The length of the first ventilation path may be greater than the width of a part of the first interposer circuit in which the first ventilation path is formed.

According to an embodiment of the disclosure, the first end may not overlap the second end, when viewed in a direction perpendicular to the outer side of the first portion at which the first end is formed.

According to an embodiment of the disclosure, the first ventilation path may include at least one bend portion.

According to an embodiment of the disclosure, the at least one bend portion may include a first bend portion and a second bend portion. The first ventilation path may include a first portion extending in a third direction from the first end to the first bend portion, a second portion extending in a fourth direction different from the third direction from the first bend portion to the second bend portion, and a third portion extending in a fifth direction different from the fourth direction from the second bend portion to the second end.

According to an embodiment of the disclosure, the fourth direction may be substantially perpendicular to the third direction, and the fifth direction may be substantially parallel to the third direction.

According to an embodiment of the disclosure, the first ventilation path of the first interposer circuit may be surrounded by the first printed circuit board and the second printed circuit board.

According to an embodiment of the disclosure, the first interposer circuit may further include a plurality of grounding pads arranged around the first ventilation path and reducing a noise signal transmitted through the first ventilation path.

According to an embodiment of the disclosure, each of the plurality of grounding pads may include at least one conductor.

According to an embodiment of the disclosure, the printed circuit board assembly may further include a grounding portion. The plurality of grounding pads may be electrically connected to the grounding portion.

According to an embodiment of the disclosure, the plurality of grounding pads may include a first grounding pad arranged between the first printed circuit board and the first interposer circuit, and a second grounding pad arranged between the second printed circuit board and the first interposer circuit.

According to an embodiment of the disclosure, the first interposer circuit may include a conductive via formed to penetrate the first interposer circuit. The first grounding pad may be electrically connected to the second grounding pad through the conductive via.

According to an embodiment of the disclosure, the printed circuit board assembly may further include a pipe connected to the first end. The air within the first space may be discharged to the outside of the first interposer circuit through the pipe.

According to an embodiment of the disclosure, the printed circuit board assembly may further include a third printed circuit board, and a second interposer circuit at least partially surrounding a second space between the second printed circuit board and the third printed circuit board. The second interposer circuit may have a second ventilation path through which the air may move from the second space to the outside of the printed circuit board assembly when the thermally conductive material is injected into the second space through the first hole formed in the first printed circuit board and a second hole formed in the second printed circuit board. The second ventilation path may connect a third end formed at an outer side, facing the outside of the printed circuit board assembly, of a fourth portion of the second interposer circuit, to a fourth end formed at an inner side, facing the second space, of the fourth portion of the second interposer circuit. The length of the second ventilation path may be greater than the width of a part of the second interposer circuit in which the second ventilation path is formed.

According to an embodiment of the disclosure, the second hole may be formed in a position corresponding to the first hole.

According to an embodiment of the disclosure, the first interposer circuit may include a third ventilation path through which the air may move from the first space to the outside of the printed circuit board assembly. The third ventilation path may be formed in a third portion of the first interposer circuit opposite to the first portion of the first interposer circuit.

According to an embodiment of the disclosure, the first portion of the first interposer circuit may include a segment portion that divides the first portion into two portions. The first ventilation path may be formed by the segment portion of the first portion of the first interposer circuit.

According to an embodiment of the disclosure, the first ventilation path may be formed by a first groove formed in one surface of the first portion of the first interposer circuit.

According to an embodiment of the disclosure, the first interposer circuit may include a fourth ventilation path formed by a second groove formed in the other surface, opposite to one surface, of the first portion of the first interposer circuit.

According to an embodiment of the disclosure, the first groove may be surrounded by the first printed circuit board. The second groove may be surrounded by the second printed circuit board.

According to an embodiment of the disclosure, a printed circuit board assembly may include a first printed circuit board including a first opening, a second printed circuit board, an interposer circuit arranged to at least partially surround a space between the first printed circuit board and the second printed circuit board, and a thermally conductive material injected into the space. The interposer circuit may include a recess formed at an inner side of a first portion of the interposer circuit in a direction of facing the outside of the printed circuit board assembly. The first opening of the first printed circuit board may be formed in a position corresponding to the recess of the interposer circuit. A ventilation path through which air may move from the space to the outside of the printed circuit board assembly may be formed by the recess and the first opening.

According to an embodiment of the disclosure, the first printed circuit board may include a second opening. The thermally conductive material may be injected through the second opening of the first printed circuit board.

The effects of the disclosure of an embodiment of the disclosure are given as follows.

According to an embodiment of the disclosure, a printed circuit board assembly may be provided in which a ventilation hole separate from a hole through which a thermally conductive material may be injected is formed in a side portion of an interposer, whereby a fluid inside the interposer may be effectively discharged through the ventilation hole without the thermally conductive material being discharged through the ventilation hole.

According to an embodiment of the disclosure, a printed circuit board assembly may be provided in which a ventilation path through which a fluid inside an interposer may move includes at least one bend portion, whereby electromagnetic waves generated by electronic components inside the interposer may be shielded by the bend portion.

In addition, various effects directly or indirectly recognized through disclosure may be provided.

The methods of the embodiments described in the claims or specification of the disclosure may be implemented in the form of hardware, software, or a combination of hardware and software.

In the case of software implementation, a computer-readable storage medium that stores one or more programs (software modules) may be provided. The one or more programs stored in the computer-readable storage medium are configured for execution by one or more processors within an electronic device. The one or more programs include instructions of allowing the electronic device to execute the methods of the embodiments described in the claims or specification of the disclosure.

These programs (software modules and software) may be stored in random access memory, non-volatile memory including flash memory, read only memory (ROM), electrically erasable programmable ROM (EEPROM), magnetic disc storage device, compact disc-ROM (CD-ROM), digital versatile discs (DVDs) or other forms of optical storage devices, magnetic cassette. Alternately, the programs may be stored in memories composed of a combination of some or all of them. In addition, each composed memory may be included in multiple as well.

In addition, the program may be stored in an attachable storage device that may be accessed through a communication network such as Internet, intranet, local area network (LAN), wide LAN (WLAN), or storage area network (SAN) or a communication network composed of a combination thereof. This storage device may be connected to a device performing an embodiment of the disclosure through an external port. In addition, a separate storage device on the communication network may be connected to a device performing an embodiment of the disclosure as well.

In the specific embodiments of the disclosure described above, components included in the disclosure are expressed in the singular or plural form according to the specific embodiments presented. However, the singular or plural expressions are selected appropriately for the presented situation for the convenience of explanation, and the disclosure is not limited to singular or plural components, and even components expressed in the plural form may be constructed in the singular form, or even components expressed in the singular form may be constructed in the plural form.

In addition, in the disclosure, the terms “part”, “module”, etc. may include hardware components such as processors or circuits, and/or software components executed by the hardware components such as processors.

“Part” and “module” may be also implemented by a program that may be stored in an addressable storage medium and executed by the processor. For example, “part” and “module” may be implemented by components such as software components, object-oriented software components, class components, and task components, processes, functions, properties, procedures, subroutines, segments of a program code, drivers, firmware, microcode, circuits, data, databases, data structures, tables, arrays, and variables.

The specific implementations described in the disclosure are only examples and do not limit the scope of the disclosure in any way. For the sake of brevity, descriptions of conventional electronic components, control systems, software, and other functional aspects of the systems may be omitted.

In addition, in the disclosure, “including at least one of a, b, or c” may mean “including only a”, “including only b”, “including only c”, “including a and b”, “including b and c”, “including a and c”, or “including all of a, b, and c”.

Meanwhile, although the detailed description of the disclosure has described specific embodiments, it is to be understood that various modifications are possible without departing from the scope of the disclosure. Therefore, the scope of the disclosure should not be limited to the described embodiments, and should be defined not only by the scope of the claims described below but also by equivalents to the scope of the claims.

What is claimed is:

1. A printed circuit board assembly comprising:
a first printed circuit board;
a second printed circuit board;
a first interposer circuit at least partially surrounding a first space between the first printed circuit board and the second printed circuit board; and
a thermally conductive material arranged within the first space,
wherein the first interposer circuit has a first ventilation path through which air moves from the first space to the outside of the printed circuit board assembly when the thermally conductive material is injected into the first space through a first hole formed in the first printed circuit board,
wherein the first ventilation path connects a first end formed at an outer side, facing the outside of the printed circuit board assembly, of a first portion of the first interposer circuit, to a second end formed at an inner side, facing the first space, of the first portion of the first interposer circuit, and
wherein the length of the first ventilation path is greater than the width of a part of the first interposer circuit in which the first ventilation path is formed.

2. The printed circuit board assembly of claim 1, wherein the first end does not overlap the second end, when viewed in a direction perpendicular to the outer side of the first portion at which the first end is formed.

3. The printed circuit board assembly of claim 1, wherein the first ventilation path comprises at least one bend portion.

4. The printed circuit board assembly of claim 3,
wherein the at least one bend portion comprises a first bend portion and a second bend portion, and
wherein the first ventilation path comprises:
a first portion extending in a third direction from the first end to the first bend portion;
a second portion extending in a fourth direction different from the third direction from the first bend portion to the second bend portion; and
a third portion extending in a fifth direction different from the fourth direction from the second bend portion to the second end.

5. The printed circuit board assembly of claim 1, wherein the first ventilation path of the first interposer circuit is surrounded by the first printed circuit board and the second printed circuit board.

6. The printed circuit board assembly of claim 1, wherein the first interposer circuit further comprises a plurality of grounding pads arranged around the first ventilation path and reducing a noise signal transmitted through the first ventilation path.

7. The printed circuit board assembly of claim 6, wherein each of the plurality of grounding pads comprises at least one conductor.

8. The printed circuit board assembly of claim 6, further comprising:
a grounding portion,
wherein the plurality of grounding pads are electrically connected to the grounding portion.

9. The printed circuit board assembly of claim 6, wherein the plurality of grounding pads comprise:
a first grounding pad arranged between the first printed circuit board and the first interposer circuit; and
a second grounding pad arranged between the second printed circuit board and the first interposer circuit.

10. The printed circuit board assembly of claim 9,
wherein the first interposer circuit comprises a conductive via formed to penetrate the first interposer circuit, and
wherein the first grounding pad is electrically connected to the second grounding pad through the conductive via.

11. The printed circuit board assembly of claim 1, further comprising:
a pipe connected to the first end,
wherein the air within the first space is discharged to the outside of the first interposer circuit through the pipe.

12. The printed circuit board assembly of claim 1, further comprising:
a third printed circuit board; and
a second interposer circuit at least partially surrounding a second space between the second printed circuit board and the third printed circuit board,
wherein the second interposer circuit has a second ventilation path through which the air moves from the second space to the outside of the printed circuit board assembly when the thermally conductive material is injected into the second space through the first hole formed in the first printed circuit board and a second hole formed in the second printed circuit board,
wherein the second ventilation path connects a third end formed at an outer side, facing the outside of the printed circuit board assembly, of a fourth portion of the second interposer circuit, to a fourth end formed at an inner side, facing the second space, of the fourth portion of the second interposer circuit, and
wherein the length of the second ventilation path is greater than the width of a part of the second interposer circuit in which the second ventilation path is formed.

13. The printed circuit board assembly of claim 12, wherein the second hole is formed in a position corresponding to the first hole.

14. The printed circuit board assembly of claim 1,
wherein the first interposer circuit comprises a third ventilation path through which the air moves from the first space to the outside of the printed circuit board assembly, and
wherein the third ventilation path is formed in a third portion of the first interposer circuit opposite to the first portion of the first interposer circuit.

15. The printed circuit board assembly of claim 1,
wherein the first portion of the first interposer circuit comprises a segment portion that divides the first portion into two portions, and
wherein the first ventilation path is formed by the segment portion of the first portion of the first interposer circuit.

16. The printed circuit board assembly of claim 1, wherein the first ventilation path is formed by a first groove formed in one surface of the first portion of the first interposer circuit.

17. The printed circuit board assembly of claim 16, wherein the first interposer circuit comprises a fourth ventilation path formed by a second groove formed in the other surface, opposite to one surface, of the first portion of the first interposer circuit.

18. The printed circuit board assembly of claim 17,
wherein the first groove is surrounded by the first printed circuit board, and
wherein the second groove is surrounded by the second printed circuit board.

19. A printed circuit board assembly comprising:
a first printed circuit board comprising a first opening;
a second printed circuit board;
an interposer circuit arranged to at least partially surround a space between the first printed circuit board and the second printed circuit board; and
a thermally conductive material injected into the space,
wherein the interposer circuit comprises a recess formed at an inner side of a first portion of the interposer circuit in a direction of facing the outside of the printed circuit board assembly,
wherein the first opening of the first printed circuit board is formed in a position corresponding to the recess of the interposer circuit, and
wherein a ventilation path through which air moves from the space to the outside of the printed circuit board assembly is formed by the recess and the first opening.

20. The printed circuit board assembly of claim 19,
wherein the first printed circuit board comprises a second opening, and
wherein the thermally conductive material is injected through the second opening of the first printed circuit board.
